(19) United States
(12) Patent Application Publication
(10) Pub. No.: US 2026/0150254 A1
(43) Pub. Date: May 28, 2026

(54) ELECTRIC POWER CONVERTER AND METHOD FOR CONDENSATION MONITORING IN ELECTRIC POWER CONVERTER

(71) Applicant: Danfoss Drives Oy, Vaasa (FI)

(72) Inventors: Jani Matti PERKIÖ, Tampere (FI); Timo VEPSALAINEN, Helsinki (FI)

(21) Appl. No.: 19/392,310

(22) Filed: Nov. 18, 2025

(30) Foreign Application Priority Data
Nov. 22, 2024 (DE) 102024134482.2

(51) Int. Cl. H05K 7/20; H02M 1/32

(52) U.S. Cl. CPC H05K 7/20945; H02M 1/327; H05K 7/20927

(57) ABSTRACT

An electric power converter (100) including a first channel (10) for a cooling gas (101) to flow in, a second channel (20) for a cooling fluid (102) to flow in, at least one first temperature determining device (14) configured for determining a first gas temperature in the first channel (10), at least one first humidity determining device (16) configured for determining a first humidity in the first channel (10), at least one second temperature determining device (24) arranged for determining a second fluid temperature in the second channel (20), and a controller (50) in connection with said sensor device. The controller (50) being configured to determine a dew point of the cooling gas (101) based on the determined first gas temperature and the first humidity, and determine a condensation risk based on the determined dew point and the second temperature.

### CROSS-REFERENCE TO RELATED APPLICATION

This application claims foreign priority benefits under 35 U.S.C. § 119 from German Patent Application No 102024134482.2, filed Nov. 22, 2024, the content of which is hereby incorporated by reference in its entirety.

### TECHNICAL FIELD

The present invention relates in general to electric power converters, such as frequency converters, inverters, and/or rectifiers. In particular, however, not exclusively, the present invention concerns condensation monitoring with respect to electric power converters.

### BACKGROUND

Condensation poses a real threat for electric power converters since these products are installed in various demanding environments all over the world. Condensation might cause a lot of unintended defects for the converter and should thus be avoided. It can cause damage to electrical and electronic components of the converter. There can potentially be short circuits, corrosion, premature breakdown, contamination by mold, water drainage from enclosures, or even risk of shock to users.

The user may not always realize that the environment where the product is installed in might cause condensation. Also, if condensation causes problems, it is afterwards difficult to analyze since after the defect, the condensed water vaporizes, thus it may not leave evidence.

The products having biggest risk for condensation are products that use cooling where the main circuit is cooled with different airflow than the control circuitry (typically outdoor air vs indoor air). One example of this may be referred to as back-channel cooling. This solution causes a large temperature difference between these two environments and could create condensation on the metal parts and electronic components inside the electrical power converter which is typically warmer than the outside. Another example that might cause condensation is with liquid cooled converters where parts cooled with cold cooling liquid are subjected to humid air.

It is known to control condensation by controlling humidity of the air within the housing and/or the device itself. For example, heaters, air conditioners, dehumidifiers, and fans can be used in the surroundings and/or inside the enclosure of the electric device to control the enclosure's internal temperature and humidity. There is, however, still a need to improve electric power converters with respect to condensation.

### SUMMARY

An objective of the present invention is to provide an electric power converter and a method for condensation monitoring in an electric power converter. Another objective of the present invention is that the electric power converter and the method enables monitoring a condensation risk in the electric power converter during use thereof in its operation environment.

The objectives of the invention are reached by an electric power converter and a method for condensation monitoring in an electric power converter as defined by the respective independent claims.

According to a first aspect, an electric power converter is provided. The electric power converter comprises a first channel for a cooling gas to flow in, a second channel for a cooling fluid, such as cooling fluid or gas, to flow in, at least one first temperature determining device configured for determining a first gas temperature in the first channel, at least one first humidity determining device configured for determining a first humidity in the first channel, and at least one second temperature determining device arranged for determining a second fluid temperature in the second channel. The electric converter also comprises a controller in connection with the at least one first temperature determining device, the at least one first humidity determining device, and the at least one second temperature determining device. The controller is configured to determine a dew point of the cooling gas based on the determined first gas temperature and the first humidity, and to determine a condensation risk based on the determined dew point and the second temperature.

The determination of the condensation risk may include the controller being configured to compare the determined dew point and the second temperature related to same time instance with each other.

The determination of the condensation risk may include the controller being configured to estimate a surface temperature of a surface in the electric power converter based on the second temperature. Preferably, the surface is subjected to the cooling gas when it flows in the first channel. In addition or alternatively, the surface is fluidly isolated relative to the second channel, thus, the surface is not directly subjected to the cooling fluid flowing in the second channel.

The electric power converter may comprise a thermally conductive path between the second channel and the surface, such as via an intermediate structure between the channels, for example, a wall portion made of metal or other thermally conductive material. The thermally conductive material may have a thermal conductivity of at least 0.7 W/(m·K) or at least 10 W/(m·K).

The controller may be configured to determine a time period for which the determined condensation risk has been higher than a predefined risk threshold value, and to store the time period into a memory.

The controller may be configured to generate an alert signal if the condensation risk is higher than a predefined acceptable condensation risk.

The controller may be configured to store into the condensation risk into a memory.

The controller may be configured to store into a memory the determined dew point and/or the second temperature with time instance information, such as with a time stamp or stamps (preferably synchronized or at least synchronizable with each other so that the dew point can be compared with the second temperature at corresponding time instances).

The controller may be configured to store into a memory the determined first gas temperature and/or the first humidity with time instance information.

The second channel may be arranged to provide back-channel cooling. This may mean having at least separate outlets for the first and the second channels.

The electric power converter preferably comprises a power conversion circuitry and a control circuitry. The power conversion circuitry may be arranged to be cooled by the cooling fluid, and the control circuitry may be arranged to be cooled by the cooling gas.

The power conversion circuitry may comprise at least power semiconductor devices utilized for providing main power conversion of the electric power converter, and optionally DC link energy storage element(s), such as DC capacitors. The power conversion circuitry may additionally comprise driver circuits for switching the power semiconductor devices. Furthermore, the power conversion circuitry may additionally comprise one or more filter components, such as filter inductor(s) and/or filter capacitors.

The control circuitry, on the other hand, may comprise electronics for providing control of the operation of the electric power converter. For example, the control circuitry may comprise the controller, such as including processing unit(s) and memory device(s), which is configured to process data from sensors, such as current and voltage sensors as well as temperature and humidity sensor(s), and to generate and provide control signals to one or more other device of the electric power converter, such as to the driver circuits.

In various embodiments, the power conversion circuitry may, at least partly, be arranged to be cooled by the cooling fluid in the second channel. For example, one or more heat sinks arranged for cooling components/devices of the power conversion circuitry may be subjected to the cooling fluid. The control circuitry, on the other hand, may at least partly be arranged to be cooled by the cooling gas in the first channel. Thus, the cooling gas may, either directly or via one or more heat sinks of the control circuitry, be arranged for cooling components/devices of the control circuitry. Therefore, requirements for cooling power may be different for components/devices in the second channel than in the first channel.

The electric power converter may comprise an output, such as a digital output port, configured to output a signal representative of the determined condensation risk, wherein the output is arranged for providing control signal to a heater and/or cooler device.

According to a second aspect, a method for condensation monitoring in an electric power converter is provided. The method comprises determining, by a controller, a dew point of a cooling gas flowing in a first channel of the electric power converter, determining, by the controller, a temperature of a cooling fluid, such as cooling liquid or second cooling gas, flowing in a second channel of the electric power converter, and determining, by the controller, a condensation risk based on the determined dew point and the second temperature.

The method may comprise comparing the determined dew point and the second temperature related to same time instance with each other.

The method may comprise determining a time period for which the condensation risk has been higher than a predefined risk threshold value, and storing the time period into a memory.

The determination of the condensation risk may include estimating a surface temperature of a surface in the electric power converter based on the second temperature. The surface is, preferably, subjected to the cooling gas when it flows in the first channel. In addition or alternatively, the surface may be fluidly isolated relative to the second channel, thus, the surface is not directly subjected to the cooling fluid flowing in the second channel.

The present invention provides an electric power converter and a method for condensation monitoring in an electric power converter. The present invention provides advantages over known solutions in that it reduces dive defects due to condensation and gives the possibility to reduce warranty cost by reading the fault memory to detect possible misuse if the product was installed in places where condensation was possible. The user can be warned of the increased condensation risk, as a result of which the user can take steps to mitigate the problem such as by decreasing humidity in the cooling gas.

Various other advantages will become clear to a skilled person based on the following detailed description.

The expression “a number of” may herein refer to any positive integer starting from one (1).

The expression “a plurality of” may refer to any positive integer starting from two (2), that is being at least two, two, at least three, three, and so on.

The terms “first” and “second” are herein used to distinguish one element from other element, and not to specially prioritize or order them, if not otherwise explicitly stated.

The exemplary embodiments of the present invention presented herein are not to be interpreted to pose limitations to the applicability of the appended claims. The verb “to comprise” is used herein as an open limitation that does not exclude the existence of also unrecited features. The features recited in the appended patent claims are mutually freely combinable unless otherwise explicitly stated.

The novel features which are considered as characteristic of the present invention are set forth in particular in the appended claims. The present invention itself, however, both as to its construction and its method of operation, together with additional objectives and advantages thereof, will be best understood from the following description of specific embodiments when read in connection with the accompanying drawings.

### BRIEF DESCRIPTION OF THE DRAWINGS

Some embodiments of the invention are illustrated by way of example, and not by way of limitation, in the figures of the accompanying drawings.

FIG. 1 illustrates schematically an electric power converter.

FIG. 2 illustrates schematically an electric power converter.

FIG. 3 shows a flow diagram of a method for a method for condensation monitoring in an electric power converter.

### DETAILED DESCRIPTION

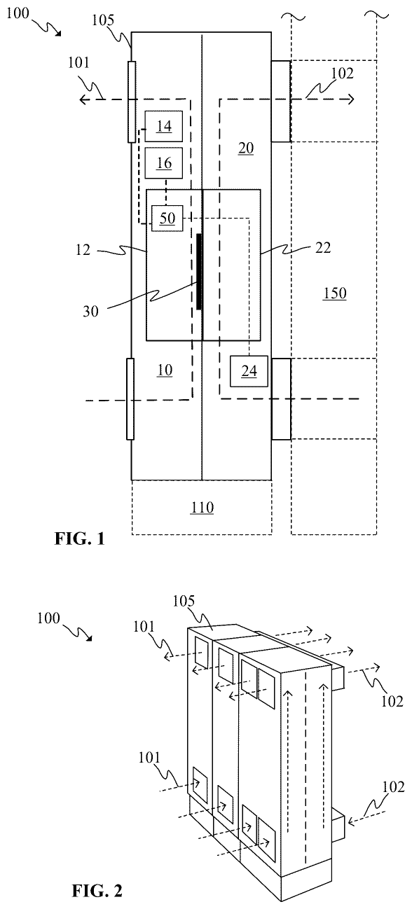

FIG. 1 illustrates schematically an electric power converter 100. The electric power converter 100 comprises a first channel 10 for a cooling gas 101 to flow in, a second channel 20 for a cooling fluid 102, such as a cooling liquid or a second cooling gas, to flow in, at least one first temperature determining device 14 configured for determining a first gas temperature in the first channel 10, at least one first humidity determining device 16 configured for determining a first humidity in the first channel 10, at least one second temperature determining device 24 arranged for determining a second fluid temperature in the second channel 20, and a controller 50 in connection with the at least one first temperature determining device 14, the at least one first humidity determining device 16, and the at least one second temperature determining device 24.

In case the cooling fluid 102 is a second cooling gas, the second cooling gas may same or different gas than the cooling gas 101. For example, the cooling gas 101 may be air and the second cooling gas 102 may be air or some other gas, or vice versa. FIG. 1 shows the cooling gas 101 and the cooling fluid 102, e.g. a cooling liquid or a second cooling gas, in a parallel flow arrangement, however, they might alternatively be

arranged in a counter flow arrangement. Furthermore, the cooling gas 101 may flow from bottom to top as in FIG. 1 or from top to bottom. The same applies to the cooling fluid 102.

The determination of the condensation risk may include the controller 50 being configured to compare the determined dew point and the second temperature related to same time instance with each other.

For example, the determination of the condensation risk may include the controller 50 being configured to estimate a surface temperature of a surface 30 in the electric power converter 100 based on the second temperature.

The surface 30 is, preferably, fluidly isolated relative to the second channel. Thus, the surface 30 is not directly subjected to the cooling fluid flowing in the second channel.

The electric power converter may comprise a thermally conductive path between the second channel and the surface 30, such as via an intermediate structure between the channels, for example, a wall portion made of metal and/or other thermally conductive material. The thermally conductive material or set of materials may have a thermal conductivity of at least 0.7 W/(m·K) or at least preferably 10 W/(m·K).

The estimation may be based on a heat transfer model, having the second temperature as an input parameter, that the controller 50 or other processing unit is arranged to run. Thus, the model may include a correction factor which may model temperature of, for example, a metal part or parts, or wall, between the first and the second, where the condensation most likely occurs.

The model may also include other parameters related to the heat transfer between a second surface that is subjected to the cooling fluid and the surface 30 subjected to the cooling gas. Thus, preferably, the surface 30 is subjected to the cooling gas 101 flowing in the first channel 10. The comparison of the dew point with the estimated surface temperature of the surface 30 provides information about possible condensation on the surface 30, such as related to times that condensation is likely or surely happening. Alternatively, the estimation may be as simple as the controller 50 being configured to assume the surface temperature to be equal to or some predefined number of degrees, such as in the range from 0.1 to 5.0 degrees Celsius, or even up to 10 degrees Celsius, lower than the second temperature.

The controller 50 may be configured to determine a time period for which the condensation risk has been higher than a predefined risk threshold value, and to store the time period into a memory. The time period may be continuous or a sum of shorter time periods, and it may, optionally, affect the determined condensation risk. The predefined risk threshold value may be chosen based on the embodiment. In various embodiments, the condensation risk may have a value ranging from zero to one, being able to have values zero and one or any value therebetween. On the other hand, the condensation risk may have only one of two values, zero or one. Thus, the choice of predefined risk threshold value may also be affected by how the condensation risk is determined. For example, in a simple case, the risk may be zero if the dew point is lower than the second temperature or the estimated surface temperature, and one if the dew point is equal or higher than the second temperature or the estimated surface temperature.

The controller 50 may be configured to generate an alert signal if the condensation risk is higher than a predefined acceptable condensation risk. The predefined acceptable condensation risk may be equal to the predefined risk threshold value. On the other hand, the predefined acceptable condensation risk may be different from, such as less than, the predefined risk threshold value.

For example, the alert signal may include three levels: green (low risk level; no dew point detected), yellow (moderate risk level; warning that the converter device is near the dew point), and red (high risk level; the dew point has been reached). The electric power converter 100 may be configured to count the number of yellow and red detections, and also summarize the time for each level, which could be used to identify how often and how long time the electric power converter 100 have been exposed to conditions which may reduce the lifetime of the electric power converter 100. This may, for example, affect maintenance or warranty.

Furthermore, yellow and red conditions may also be used to trigger a heater and/or cooler device, such as including a heating element and/or a fan, in connection with the electric power converter 100, such as located on the backside of the electric power converter 100. For example, yellow condition may result in the activation of the fan at low speed, and in red condition in the activation of the fan at high speed in order to avoid dew and moisture to condensate onto the internal electronics and mechanical parts of the electric power converter 100 and to cause reduced lifetime due damages. Of course, the invention is not limited to a specific number of levels but may be any plural number of levels.

The detections of dew may be a part of condition-based monitoring which involves acquiring a baseline which is stored in the electric power converter 100 or a cloud storage system, then later compared the actual data during usage with the base-line and detect any time instances of where the dew point and/or the condensation risk threshold has been exceeded.

In some embodiments, in addition to the time instance by time instance comparison of the second temperature or the estimated surface temperature with the dew point, the amount of time during which the second temperature or the estimated surface temperature has been continuously equal or lower than the dew point can also be configured to affect the determination condensation risk. Thus, short time periods with such condition may not increase the risk as much as having longer time period with said condition persisting continuously.

The controller 50 may, preferably, be configured to store the determined condensation risk into a memory. Thus, history data of the condensation risk can easily be analyzed.

The controller 50 may be configured to store into a memory the determined dew point and/or the second temperature with time instance information. This information may be utilized afterwards to redetermine the condensation risk in a different manner and/or in diagnostic purposes, such as related to operation of the sensors or the like.

The controller 50 may, in addition or alternatively, be configured to store into a memory the determined first gas temperature and/or the first humidity with time instance information. Thus, the dew point may be redetermined and/or analyzed afterwards, or used in diagnostic purposes.

FIG. 1 also illustrates that the electric power converter 100 may comprise a power conversion circuitry 22 and a control circuitry 12. The power conversion circuitry 22 may be arranged to be cooled by the cooling fluid 102, and the control circuitry 12 may be arranged to be cooled by the cooling gas 101. The electric power converter 100 may or may not comprise a cabinet 105 inside of which comprises the power conversion circuitry 22 and the control circuitry 12.

In some embodiments, the electric power converter 100 may comprise an output (not shown), for example, a digital output port, configured to output a signal representative of the determined condensation risk, wherein the output is arranged for providing control signal to a heater and/or cooler device (not shown). The heater and/or cooler device may be arranged into the cabinet 105 of the electric power converter 100 or in connection with the inlet of the first channel 10 and/or of the second channel 20 of the electric power converter 100. Alternatively, the heater and/or cooler device may be arranged to the same room than the electric power converter 100, whether there is a cabinet 105 or not. Thus, the heater and/or cooler device may be used selectively only or mostly when the condensation risk is high to lower it or preventing it to go higher.

There may also be, optionally, a pedestal 110 arranged to or in connection with the electric power converter 100. Alternatively, the electric power converter 100 may be attached to a support structure, such as on a back wall 150 or directly to the back wall 150.

FIG. 1 also illustrates the back wall 150, close to or against which the electric power converter 100 may be arranged. There may be channels in the back wall 150 to which the second channel 20 of the electric power converter 100 may be connected to allow the flow of the cooling fluid 102 through the back wall 150 and into the second channel 20, thus enabling back-channel cooling.

In some embodiments, an inlet of the second channel 20 may be in the same space than an inlet of the first channel 10, however, an outlet of the second channel 20 being connected to the channel of the back wall 150 or other support structure. Thus, the heated cooling fluid 102 may be removed from the space where the electric power converter 100 is installed in.

FIG. 2 illustrates schematically an electric power converter 100 with a perspective view. FIG. 2 shows the flow of cooling gas 101, such as air, and the cooling fluid 102, such as e.g. water or air, via the corresponding inlets and outlets.

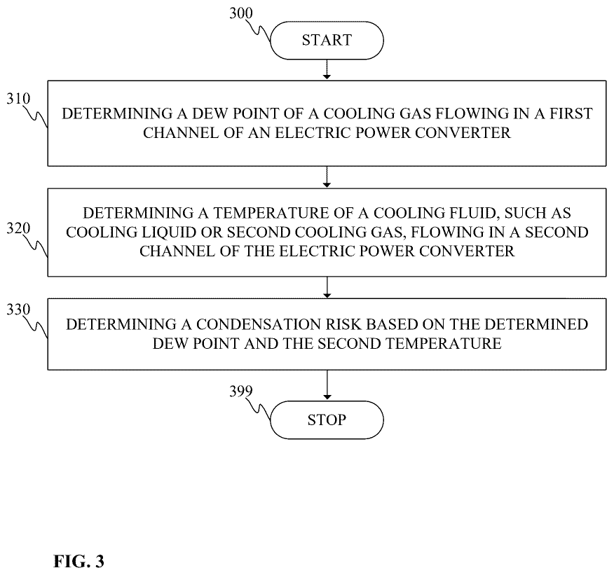

FIG. 3 shows a flow diagram of a method for a method for condensation monitoring in an electric power converter 100.

Item or method stop 300 refers to an optional start-up phase of the method. It may include setting up the electric power converter 100 to be ready for operation.

Item or method stop 310 refers to determining, such as by a controller 50, a dew point of a cooling gas 101 flowing in a first channel 10 of the electric power converter 100.

Item or method stop 320 refers to determining, such as by the controller 50, a temperature of a cooling fluid 102 flowing in a second channel 20 of the electric power converter 100.

Item or method stop 330 refers to determining, such as by the controller 50, a condensation risk based on the determined dew point and the second temperature. The method may comprise comparing the determined dew point and the second temperature related to same time instance with each other.

The determination of the condensation risk may further include estimating a surface temperature of a surface 30 in the electric power converter 100 based on the second temperature.

Optionally, the method may comprise determining a time period for which the condensation risk has been higher than a predefined risk threshold value, and storing the time period into a memory.

In some embodiments, the method may comprise outputting a signal representative of the determined condensation risk for controlling a heater and/or cooler device.

The method may be stopped at item or method step 399.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. An electric power converter comprising:
a first channel for a cooling gas to flow in,
a second channel for a cooling fluid, such as a cooling liquid or a second cooling gas, to flow in,
at least one first temperature determining device configured for determining a first gas temperature in the first channel,
at least one first humidity determining device configured for determining a first humidity in the first channel,
at least one second temperature determining device arranged for determining a second fluid temperature in the second channel, and
a controller in connection with the at least one first temperature determining device, the at least one first humidity determining device, and the at least one second temperature determining device, the controller being configured to:
determine a dew point of the cooling gas based on the determined first gas temperature and the first humidity, and
determine a condensation risk based on the determined dew point and the second temperature.

2. The electric power converter of claim 1, wherein the determination of the condensation risk includes the controller being configured to compare the determined dew point and the second temperature related to same time instance with each other.

3. The electric power converter of claim 1, wherein the determination of the condensation risk includes the controller being configured to estimate a surface temperature of a surface in the electric power converter based on the second temperature.

4. The electric power converter of claim 3, wherein the surface is subjected to the cooling gas when it flows in the first channel.

5. The electric power converter of claim 3, wherein the surface is fluidly isolated relative to the second channel.

6. The electric power converter of claim 3, comprising a thermally conductive path between the second channel and the surface.

7. The electric power converter of claim 1, wherein the controller is configured to determine a time period for which the condensation risk has been higher than a predefined risk threshold value, and to store the time period into a memory.

8. The electric power converter of claim 1, wherein the controller is configured to generate an alert signal if the condensation risk is higher than a predefined acceptable condensation risk.

9. The electric power converter of claim 1, wherein the controller is configured to store the condensation risk into a memory.

10. The electric power converter of claim 1, wherein the controller is configured to store into a memory the determined dew point and/or the second temperature with time instance information.

11. The electric power converter of claim 1, wherein the controller is configured to store into a memory the determined first gas temperature and/or the first humidity with time instance information.

12. The electric power converter of any claim 1, wherein the second channel is arranged to provide back-channel cooling.

13. The electric power converter of claim 1, comprising a power conversion circuitry and a control circuitry, wherein the power conversion circuitry is arranged to be cooled by the cooling fluid, and the control circuitry is arranged to be cooled by the cooling gas.

14. The electric power converter of claim 1, comprising an output configured to output a signal representative of the determined condensation risk, wherein the output is arranged for providing control signal to a heater and/or cooler device.

15. A method for condensation monitoring in an electric power converter, the method comprising:
determining, by a controller, a dew point of a cooling gas flowing in a first channel of the electric power converter,
determining, by the controller, a temperature of a cooling fluid, such as liquid or gas, flowing in a second channel of the electric power converter, and
determining, by the controller, a condensation risk based on the determined dew point and the second temperature.

16. The method of claim 15, comprising determining a time period for which the condensation risk has been higher than a predefined risk threshold value, and storing the time period into a memory.

17. The method of claim 15, wherein the determination of the condensation risk includes estimating a surface temperature of a surface in the electric power converter based on the second temperature.

18. The method of claim 15, comprising comparing the determined dew point and the second temperature related to same time instance with each other.

19. The method of claim 15, comprising outputting a signal representative of the determined condensation risk for controlling a heater and/or cooler device
